(19) United States
(12) Patent Application Publication
(10) Pub. No.: US 2026/0080116 A1
(43) Pub. Date: Mar. 19, 2026

(54) METHOD AND SYSTEM FOR DETERMINING A FRONT END STRUCTURE OF A VEHICLE TO MEET A SMALL OFFSET BARRIER TEST

(71) Applicant: FCA US LLC, Auburn Hills, MI (US)

(72) Inventors: Malli Kartheek Yalamanchili, Auburn Hills, MI (US); Nitin Sharma, Auburn Hills, MI (US)

(21) Appl. No.: 18/886,048

(22) Filed: Sep. 16, 2024

(51) Int. Cl. G06F 30/15; B62D 65/00

(52) U.S. Cl. CPC G06F 30/15; B62D 65/00

(57) ABSTRACT

A method of determining a front end vehicle design forming a plurality of control factors for a front structure of a vehicle, each control factor comprising a first level and a second level, selecting a first level or a second level for each control factors based on a crash velocity and an amount of energy absorbed and forming a vehicle design output corresponding to the first level or the second level based on selecting.

### FIELD

The present disclosure relates to a front end structure of a vehicle and, more specifically, to a method and system for determining the configuration of a vehicle from structure to meet a small offset barrier test.

### BACKGROUND

This section provides background information related to the present disclosure which is not necessarily prior art.

Vehicles must pass certain governmental requirements in order to be certified for public use. One test that vehicles must pass is a small offset rigid barrier (SORB) test. The SORB test simulates a real-word scenario where the front of the vehicle collides with another car or object like a tree or utility pole. The SORB test is conducted at about 64.4 kilometers per hour at a 25% overlap. The test is challenging for the automotive industry in that the vehicle energy absorbing structure does not engage the barrier directly during the crash event. Minimizing structural damage and intrusion into the passenger compartment is important. To meet the rigors of the SORB test, the vehicle structure must be chosen. However, choosing a vehicle structure involves tradeoffs. Some components can significantly increase the weight of a vehicle. Reducing weight is also typically a goal for a vehicle. Determining an effective structural approach to the front end of the vehicle is important.

### SUMMARY

This section provides a general summary of the disclosure, and is not a comprehensive disclosure of its full scope or all of its features.

The present system and method provides a determination of an improved front end structure for a vehicle with components that contribute to improving small offset rigid crash events without unnecessarily providing components that make a contribution.

In one aspect of the disclosure, a method of determining a front end vehicle design forming a plurality of control factors for a front structure of a vehicle, each control factor comprising a first level and a second level, selecting a first level or a second level for each control factors based on a crash velocity and an amount of energy absorbed and forming a vehicle design output corresponding to the first level or the second level based on selecting.

In another aspect of the disclosure, a system includes a processor and a non-transitory computer readable medium including instructions that are executable by the processor. The instructions include forming a plurality of control factors for a front structure of a vehicle, each control factor comprising a first level and a second level, selecting a first level or a second level for each control factor based on a crash velocity and an amount of energy absorbed and forming a vehicle design output corresponding to the first level or the second level for each control factor based on selecting.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a perspective view of a front end module of a vehicle.

FIG. 2A is a block diagrammatic view of the control system of the present disclosure.

FIG. 2B is a high level flow chart of the operation of the system.

FIG. 3A is a table with control factors and levels associated therewith.

FIG. 3B is a table illustrating various build configurations for different levels illustrated in FIG. 3A.

FIG. 4A is a graph of various control factors and their associated signal to noise ratios.

FIG. 4B is a simplified version renumbered from FIG. 4A.

FIG. 4C is the plot of FIG. 4B having the baseline and optimized designs highlighted.

FIG. 4D is a summarized chart of the baseline versus optimized levels of the graph of FIG. 4C.

FIG. 4E is a table illustrating optimized results elements.

FIG. 4F is a table illustrating control factors ranked according to the signal to noise ratio numbers.

FIG. 5 is a table of predicted versus confirmed SORB test results with an indicator corresponding to the amount of a percent of confirmation.

FIG. 6A is an illustration of a table for a similar vehicle with internal combustion engine components and battery electric vehicle components.

FIG. 6B is a plot of a confirmation run test results for a SORB test using predicted and confirmed values for optimized design and a baseline design.

FIG. 7A is flowchart for performing the method of the present disclosure.

FIG. 7B is a flowchart of a method for confirming the results using SORB test analysis.

Corresponding reference numerals indicate corresponding parts throughout the several views of the drawings.

### DETAILED DESCRIPTION

Example embodiments will now be described more fully with reference to the accompanying drawings.

A portion of a vehicle 10 is illustrated. In this example, a front structure 12 is coupled to a frame 14. The front structure 12 has many components that are or may be used to reduce the amount of energy provided at the frame 14. A plurality of load paths are outboard of the vehicle so that the vehicle 10 engages the barrier with the structure to transfer load to the main rail to absorb.

The front end structure or front end module 12 may include various control factors that have different levels as will be described in greater detail below. For example, the front structure 12 includes a main rail splay 16 that has two different levels of possibilities. A lower load path may include a wheel catcher 20 and a splayed lower cradle 22.

An upper load path sweep 24 may also be included. A main rail gusset 26 is also set forth. An upper load path height above the ground the vehicle is riding upon may also be provided. A bumper gusset 28 may also be provided. A shock tower base 30 may also be provided in the front structure 12.

In addition, the front end module 12 may also have various positions relative to the frame 14. What is the FEM location “MP” mean?

A front end module design is alternately determined from a plurality of control factors. The control factors include the components set forth above and different options or levels associated with each of the control factors. The interaction of some of the control factors may also be considered. The selection of the control factors and the various levels associated therewith are set forth in greater detail below. Ultimately, a front end module 12 having the selected control factors is presented so that a design may be verified and established. The verification process, as will be described below, may be set forth relative to a longitudinal axis 40. The front of the vehicle is toward the bumper gusset 28. The regions from the front of the vehicle to the frame 14 may be divided in three different portions B₁, B₂ and B₃, ordered front to rear relative to the vehicle. The predictions and confirmations for the small offset rigid barrier test may be divided into these three regions as set forth below.

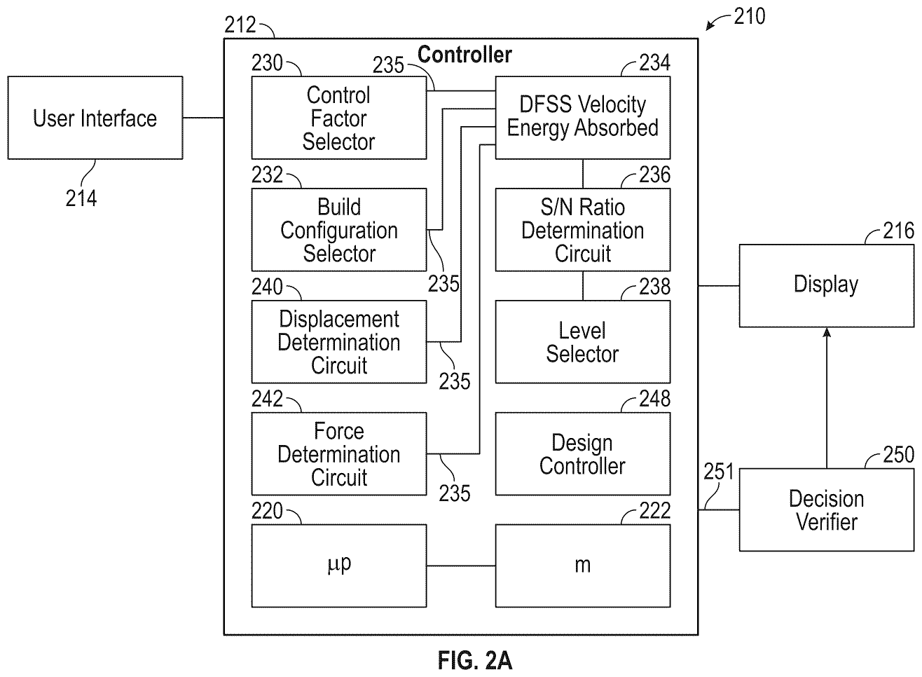

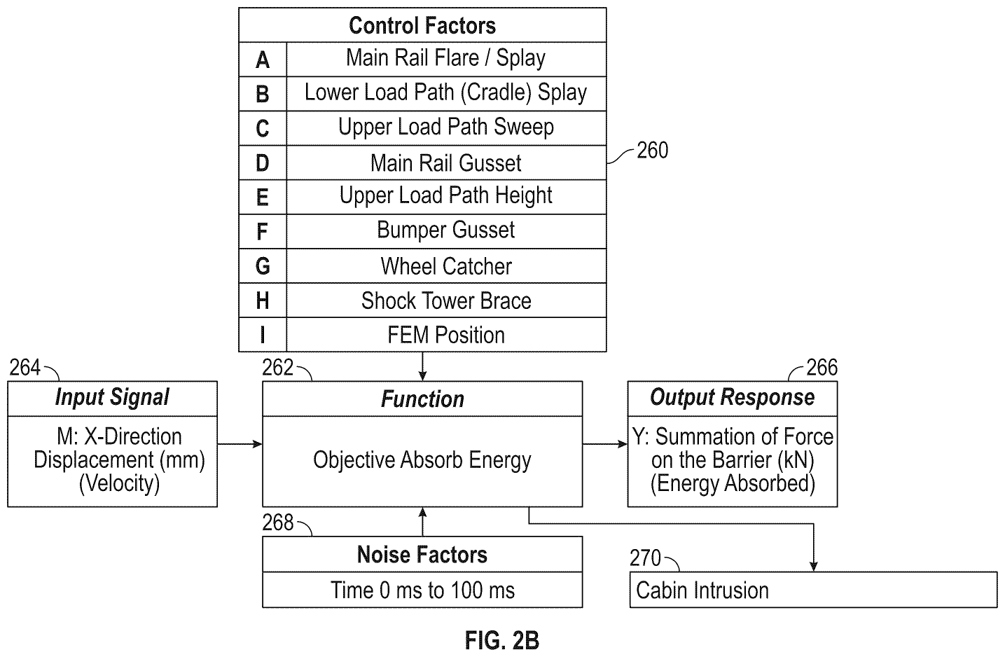

Referring now to FIG. 2, a control system 210 for determining a front end module design is set forth. The control system 210 has a controller 212 that has a user interface 214 coupled thereto. The user interface 214 may include a keyboard, a house, a stylus, a touchscreen or the like. The user interface may be used to generate selection signals for selecting or inputting various aspects of the designs and initiating the process. Ultimately, a design or verification may be generated on a display 216 that is coupled to the controller 212.

The controller 212 has one or more microprocessors represented by the microprocessor 220. The microprocessor 220 is coupled to a memory 222. The memory 222 may be a non-transitory computer-readable medium that includes machine-readable instructions that are executable by the processor. The machine readable instructions are used to perform the functions as set forth below.

The controller 212 includes a control factor selector 230. The control factor selector 212 is used for selecting various control factors for the analysis. Various components of the front end module may be used as control factors. Each of the control factors may have a first level and a second level. The levels may correspond to an existing of the first design and a changed or second design as a second level. Examples of the level within control factors are provided below.

Ultimately, a build configuration selector 232 is used to arrange the various control factors and the levels into various groups that are analyzed by a computer-aided engineering system (CAE) with a CAE process which, in this example, is a design for six sigma system (DFSS) 234. The DFSS system 234 processes the build configurations corresponding to the different versions of control factors and levels. The DFSS system 234 is shown as part of the control system 10. The components of the control system 210 may be located remotely and have the data and results transmitted through a network 235 therebetween. Ultimately, the DFSS system 234 obtains velocity and energy absorbed. The velocity and energy absorbed are used to obtain a signal to noise ratio in the signal to noise ratio determination circuit 236. Ultimately, a level selector 238 for each of the pull factors. The DFSS 234 may also determine a displacement in a determination circuit 240 and a force in a force determination circuit 242. Ultimately, the level selector 238 selects the level based on the velocity and energy absorbed (signal-to-noise ratio) which may use the displacement and force determination in the displacement termination circuit 240 and the force determination circuit 242. The level selector 238 may determine an optimized response based on the signal to noise ratios for various control factors. Ultimately, the difference between the baseline design and an optimized design may be subtracted to obtain a difference. A design controller 248 ultimately may generate a design for a front end module that is displayed on the display 216. A design verifier 250 may be used to verify the selected design relative to an offset rigid barrier test. The design verifier 250 may be located remotely and may receive a build configuration through a network 251. The design verifier performs a simulated offset rigid barrier test using the selected build configuration which is a vehicle design output from the design controller. That is, a predicted output and a confirmed output for various regions of the front end module of the vehicle may be obtained to determine whether the build configuration design is suitable for use in a final build configuration based on the simulated offset rigid barrier crash results. If the correlation or confirmation is good, then an indicator may be displayed on the display 216.

Referring now to FIG. 2B, a high level flowchart of the operation of the system is set forth. In general, a plurality of control factors 260 that correspond to the front end module are set forth. The control factors 260 in this example include a main rail flair that may be splayed, a lower load path cradle that may be splayed, an upper load path sweep, a main rail gusset, an upper load path height, a bumper gusset, a wheel catcher, a shock tower brace or a front end module position. Different control factors 260 may be determined for different front end designs. Ultimately, the control factors 260 are used to absorb energy in function block 262. An input signal, in function block 264, is provided to the function block 262. The displacement corresponds to the input velocity for the system. The input velocity may be determined from the displacement determination circuit 240 and the DFSS in block 234. After absorbing energy, the output response is the summation of the forces on the barrier or the energy absorbed in block 266. The energy absorbed by the barrier will be reduced after performing the process of the system set forth herein. Noise factors 268 may also be input to the function block 262 and considered in the computer-aided engineering module or DFSS system 234 of FIG. 2A.

The DFSS system 234 may also be used to determine cabin intrusion at block 270. Although cabin intrusion 270 may be determined, the focus of the present system is the signal to noise ratio which is the input velocity determined at block 264 to noise ratio which corresponds to the energy absorbed by the barrier in block 266. By determining the signal to noise ratios of various build configurations, an optimum build configuration may be determined as described in greater detail below.

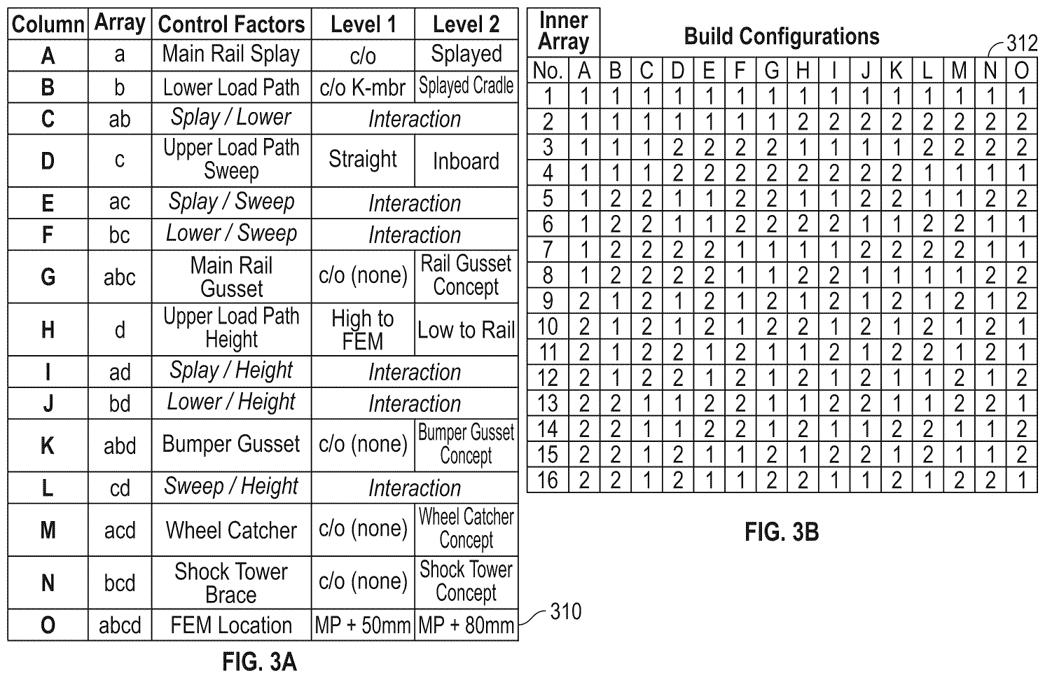

Referring now to FIGS. 3A and 3B, a table 310 having a plurality of control factors used for generating build configurations in table 312 is set forth. In this example, a plurality of columns with rows labeled A-O are set forth. These correspond to the upper row of the table 312. The array column corresponds to a control factor or interaction of control factors such as the main rail splay in the first row and a lower load path in the second row. The third row is an interaction of the first two rows. That is, the third row is the interaction of the main rail splay and the lower load path. The third row is the upper load path sweep. The fourth row is an interaction of the main rail splay (a) and the upper load path sweep (c). The sixth row is the interaction of the lower load path (b) and the upper load path sweep (c). Each of the rows has a level which, in this example, corresponds to Level 1 and Level 2. Level 1, in row A, corresponds to a carryover (c/o) or first design. The carryover member at Level 1 merely corresponds to one design for the main rail splay. Level 2, in row A, corresponds to a splayed configuration. Row B is a carryover cross-member at Level 1 and a splayed cradle at Level 2. Row D corresponding to the upper load path sweep has a straight member at Level 1 and an inboard member at Level 2. In Row G, the Level 1 configuration has no main rail gusset. Level 2 of Row G corresponds to a new rail gusset labeled a “concept”. Row H has a high to front end module at Level 1 and a low to rail at Level 2. Rows K, M and N have no bumper gusset, wheel catcher or shock tower brace at Level 1. Level 2 corresponds to a bumper gusset concept, a wheel catcher concept and a shock tower concept, respectively. Thus, the presence or absence of the various components may be determined at the computer-aided engineering or DFSS system 234.

The build configuration table 312 was operated with a plurality of levels corresponding to each of the rows in the table 310. That is, each of the columns in table 312, labeled A-O, correspond to the rows in table 310. The rows of table 312 correspond to various build configurations that are processed through the DFSS system 234 to obtain a signal to noise ratio. Various combinations, including all potential combinations, may be tested. In the present example, 16 rows correspond to 16 build configurations are set forth. The interaction of the various components is determined in the DFSS system 234 to obtain the signal to noise ratio as mentioned above. In table 312, the first row corresponds to Level 1 of each row of table 310. The second row for rows A-G corresponds to Level 1 which columns H-O correspond to Level 2 of table 310. Various other combinations of levels are performed for each of the remaining build configurations. By analyzing the various build configurations, the signal to the noise ratios of Levels 1 and 2 are determined.

The control factors and their associated signal to noise ratios for each level are plotted in table 410. The average signal to noise ratio for all of the control factors is provided at line 412. The signal to noise ratios are plotted for each level of each control factor. For example, box 414 has the signal to noise ratio for column A corresponding to the main rail splay at both Level 1 and Level 2. The rows in FIG. 3A that do not correspond to interactions have boxes 414-430 respectively applied thereto. These are referred to as the “main” control factors because the difference between Level 1 and Level 2 for each of the control factors is the greatest.

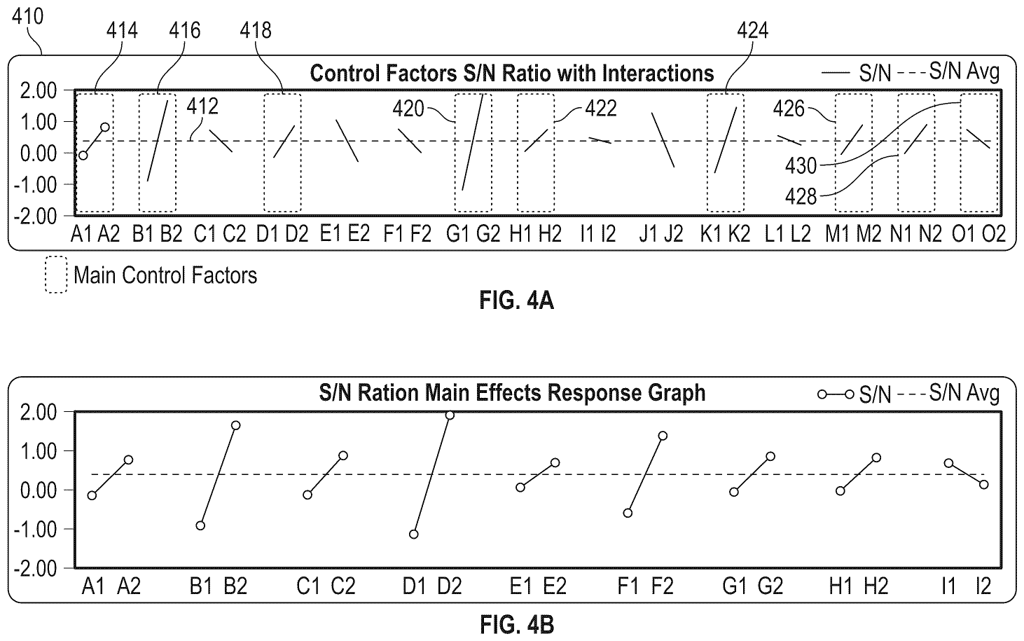

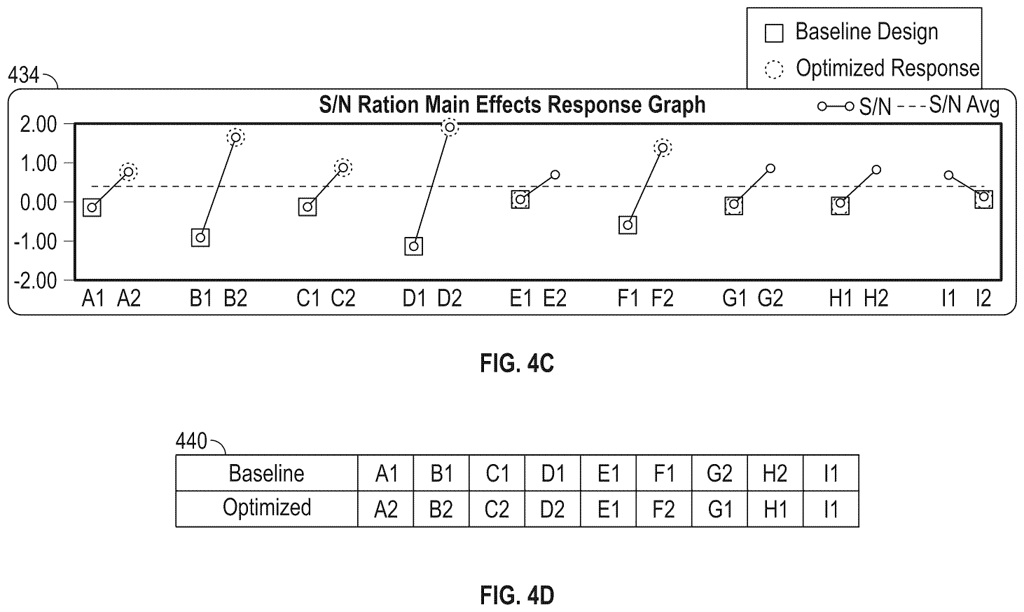

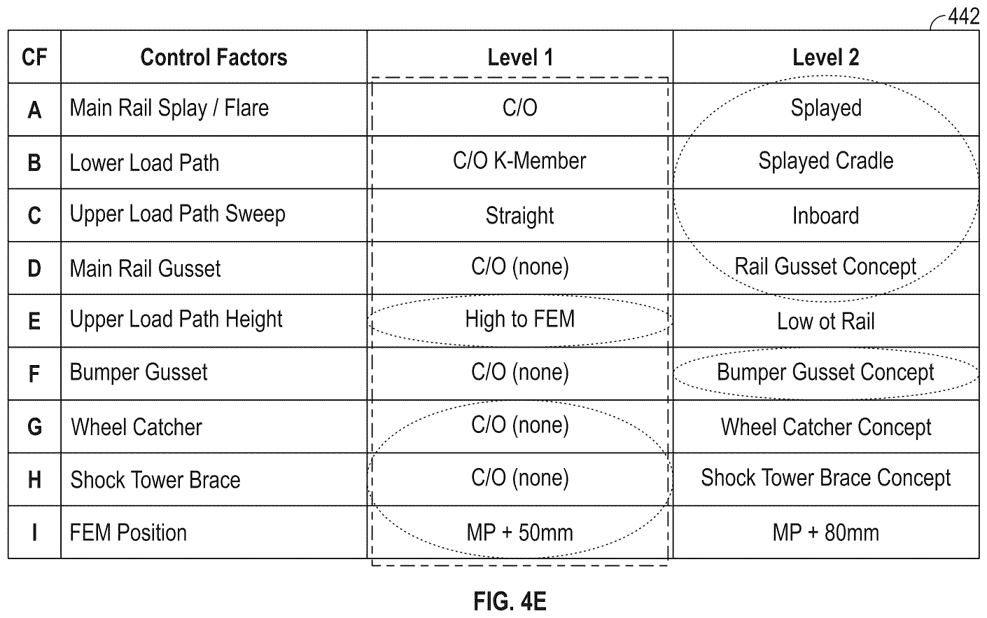

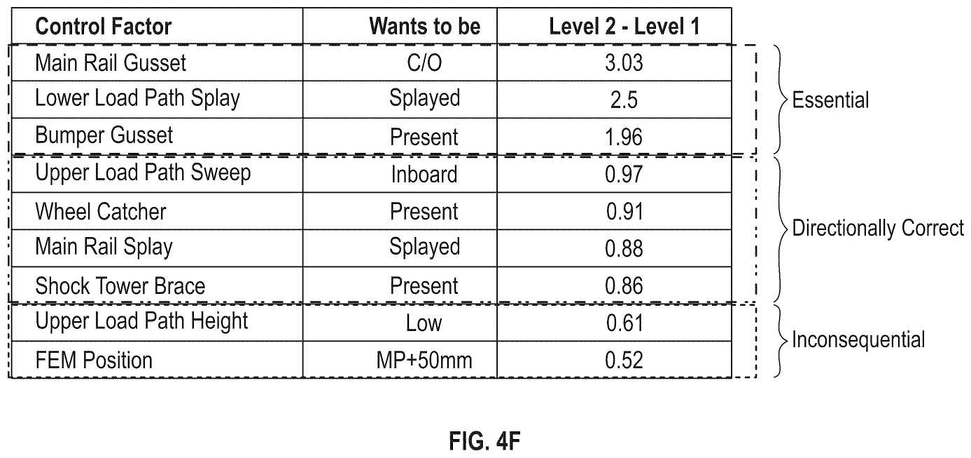

In FIG. 4B, the main control factors with boxes 414-430 are renumbered and plotted with the boxes therearound removed. Control factors A and B are the same. However, control factor D has been relabeled C. Control factor G is now D, control factor H from FIG. 4A is now E, control factor F was from control factor K of FIG. 4A and control factors G, H, and I of FIG. 4B correspond to M, N and O of FIG. 4A.

Referring now to FIGS. 4C, 4D and 4E, the baseline design and the optimized responses are identified by a box or circle at each end point of the signal to noise ratio plots from FIG. 4B. When the difference is small between Level 1 and Level 2, such as in the signal to noise ratio of control factor E, control factor G, control factor H and control factor I, the baseline design and the optimized response are chosen as the same level. This prevents unnecessary weight from being added to the vehicle by incorporating components that are not required.

The table 440 summarizes the baseline and optimized positions of the table 434 of FIG. 4C.

Referring now to FIG. 4E, a summary table with the optimized responses circled is illustrated.

Referring now to FIG. 4F, the differences between Level 2 and Level 1 signal to noise ratios are set forth. As illustrated in FIG. 4C, the differences are clearly illustrated with D1 clearly having the longest vertical distance between the baseline and the optimized response. Control factor D1 corresponds to the main rail gusset as illustrated in the table 442 of FIG. 4E. The main rail gusset, the lower load path splay and the bumper gusset have differences of 3.03, 2.5 and 1.96, respectively. The ranked control factors, in this example, are divided into three groups corresponding to an essential group, a directional correct group and an inconsequential group. That is, when the differences are greater, a bigger effect on the SORB crash barrier ratings is achieved. Therefore, at least the “essential” control factors and their associated levels are incorporated into a design for the front end module 12. Some of the “directional correct” grouping may be implemented as well but may be optional.

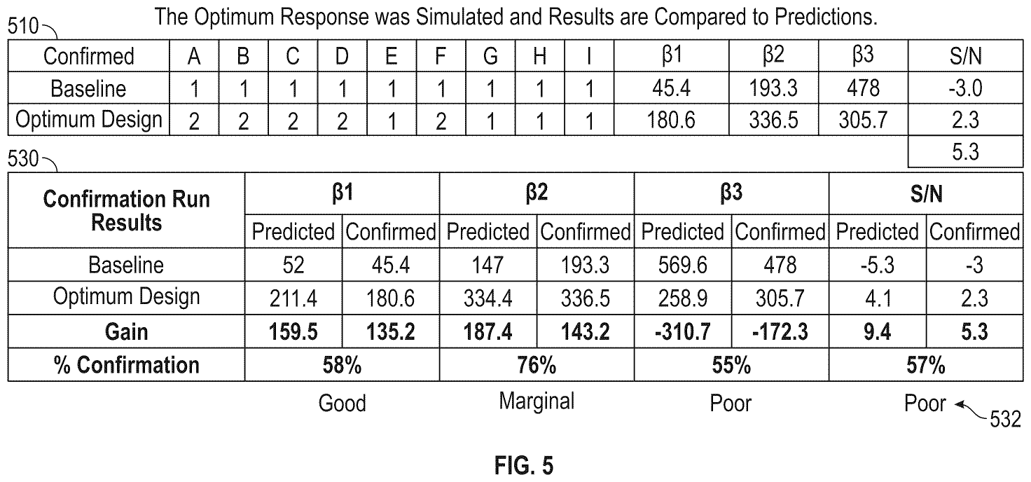

Referring now to FIG. 5, the table for portion 5 illustrates the confirmed data and the associated level for three regions B1, B2 and B3 of the front end module 12 of the vehicle when a simulated offset rigid barrier test is performed. Table portion 530 correlates the baseline and optimized designs and predicted versus confirmed for the different regions of the front end module. Above 80%, in this example, is considered corresponding to a good prediction. 60 to 80% confirmation is a marginal correlation and below 60% is considered a poor confirmation. The gain between a predicted and confirmed design for a build configuration is provided. When the gain has high confirmation, the design is confirmed in table 530. The “good”, “marginal,’ “poor” indicators 532 for each region and the signal-to-noise ratio may be displayed at the display 216.

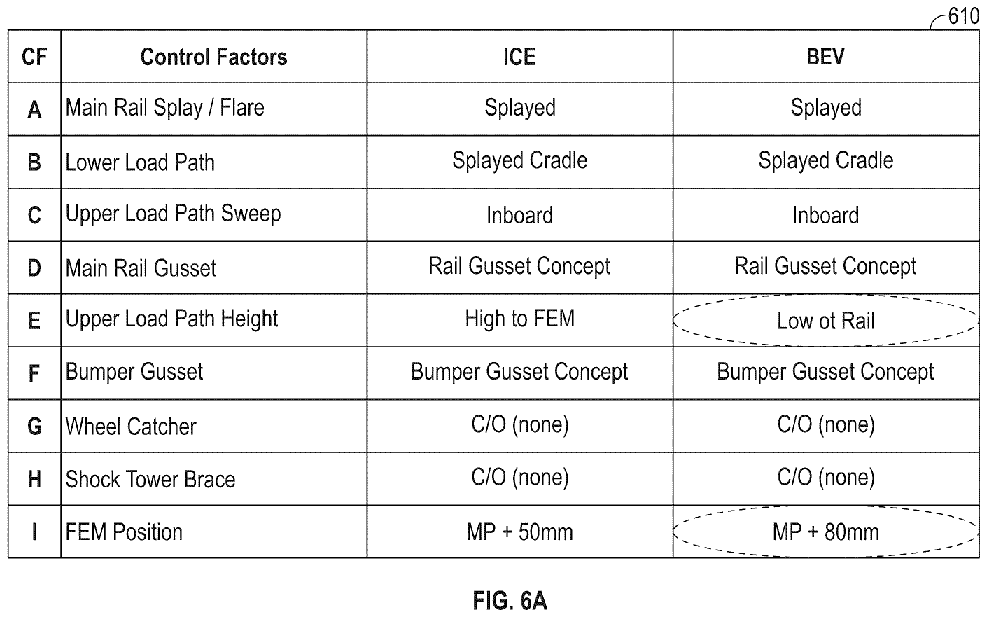

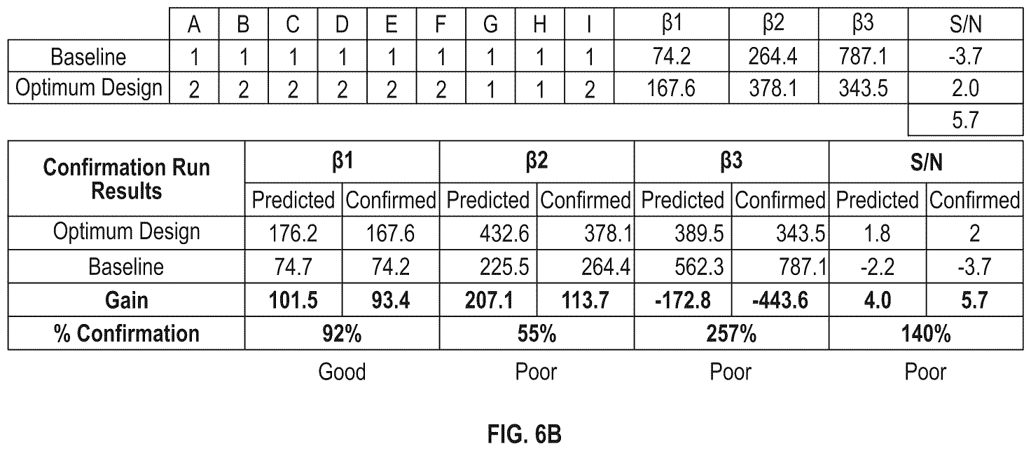

Referring now to FIG. 6, a similar table 610 to that set in FIG. 4E is provided. In this example, the second column corresponds to an internal combustion engine design versus a battery electric vehicle design in the last column. The computer-aided engineering DFSS system is used to analyze both an electric vehicle and an internal combustion engine.

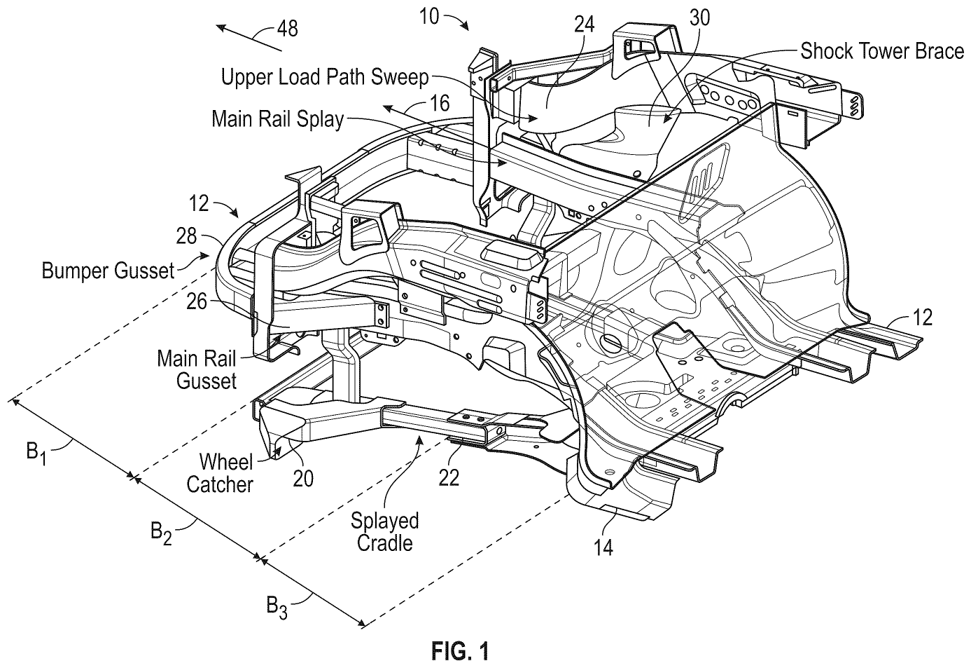

In FIG. 6B, the results show good results and good confirmation in the front region B1 of the design of the front end module of the vehicle. The difference between the battery electric vehicle and the internal combustion engine vehicle are the same except for the load path and the FEM position. The table in FIG. 6B shows the confirmation results for a battery electric vehicle in the SORB test. A prediction versus confirmation results for the SORB test are provided for a battery electric vehicle. The good correlation provides meaningful results to allow the design to proceed. That is, the design may be displayed on a display that corresponds to the front end module illustrated in FIG. 1.

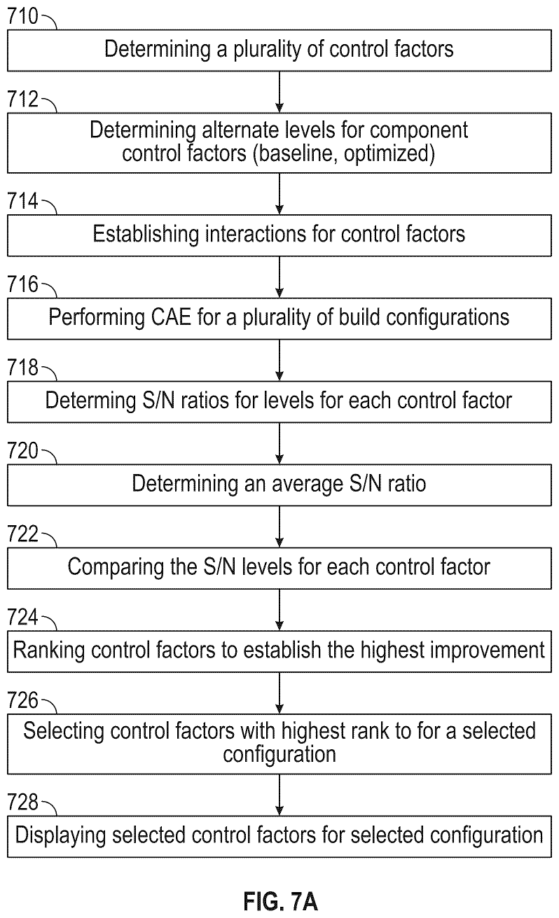

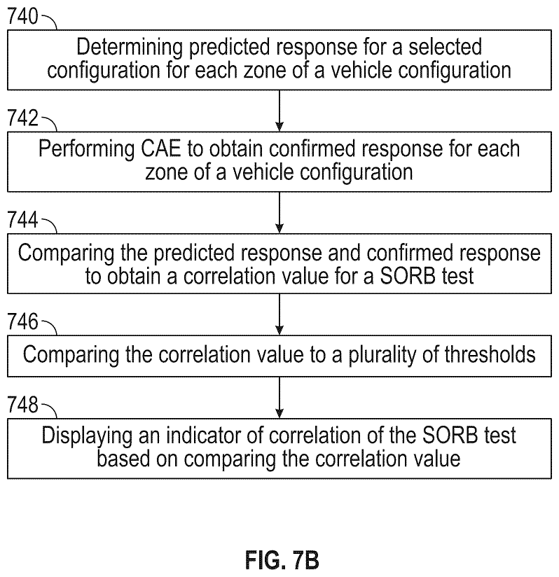

Referring now to FIG. 7A, the process starts by determining a plurality of control factors as described above. The control factors correspond to various structural elements of the vehicle or interactions thereof. The control factors have alternate levels as set forth in step 712. The alternate levels are a baseline and optimized components. Some of the components may be for a first or baseline design while other components may have an optimized or change design. Providing the right balance to perform the SORB test is performed in the present disclosure.

In step 714, the interactions of the control factors are established. That is, the established interactions may be used for testing and determining a signal to noise ratio. In step 716, the CAE analysis using the DFSS system is used for a plurality of build configuration. That is, a plurality of build configurations with combinations of Level 1 and Level 2 for the control factors is provided. In step 718, the signal to noise ratios for the levels of each control factor for all the different build configurations are set forth. This allows the interaction of the various components and various levels of components to be analyzed.

In step 720, an average signal to noise ratio is determined as illustrated in FIG. 4A. In step 722, the signal to noise ratio levels for the different levels for each control factor are determined. A plot such as FIG. 4A or FIG. 4B may be provided. However, a plot is not necessarily displayed. In step 722, the signal-to-noise ratios are compared. In one example, the Level 2 signal to noise ratios is subtracted from the Level 1 signal to noise ratio. In step 724, the control factors are ranked to establish the highest improvement. In step 726, the control factors with the highest rank are selected for a build configuration. For example, in FIG. 4F, the most improvement was achieved by selecting the three highest control factors. However, a greater number or lesser number of control factors may be selected.

In step 728, the selected control factors may be displayed numerically such as in FIG. 4F or graphically as illustrated in FIG. 4E.

Referring now to FIG. 7B, the results may be confirmed with a simulated small offset rigid barrier (SORB) test. In step 740, the predicted response for a selected design configuration for each zone of a vehicle configuration may be performed. The predicted response is the predicted response for a SORB test. Step 742, a CAE analysis using the DFSS system 234 in FIG. 2 may be performed. In step 744, the predicted response and the confirmed response are performed to obtain a correlation value for a SORB test. In step 746, the correlation value is compared to a plurality of thresholds for each of the zones of the vehicle. As illustrated in FIG. 6, three zones for the front end module may be used. In step 748, an indicator of correlation such as that illustrated in row 532 of FIG. 5 may be provided. A good indicator may indicate that a particular design configuration may be used to improve the SORB test. The output may also be generated corresponding to the table in FIG. 4E or 4F or both.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method comprising:
forming a plurality of control factors for a front structure of a vehicle, each control factor comprising a first level and a second level;
selecting a first level or a second level for each control factors based on a crash velocity and an amount of energy absorbed; and
forming a vehicle design output corresponding to the first level or the second level based on selecting.

2. The method of claim 1 wherein selecting the first level or the second level for each control factor is based on a signal to noise ratio
3. The method of claim 1 wherein the control factors further comprise interactions between control factors.

4. The method of claim 1 wherein the control factors comprise a carry over design and a changed design.

5. The method of claim 1 wherein prior to selecting the first level or a second level determining a plurality of build configurations.

6. The method of claim 5 wherein determining the plurality of build configurations comprises determining a plurality of build configurations comprising a plurality of different levels for each control factor.

7. The method of claim 6 wherein after determining the plurality of build configurations comprises performing a computer aided engineering process for the plurality of build configurations and determining a signal to noise ratio of each of the build configurations.

8. The method of claim 7 further comprising ranking the control factor.

9. The method of claim 8 wherein selecting the vehicle design output comprises selecting the vehicle design output based on ranking.

10. The method of claim 7 wherein selecting the first level or the second level comprises selecting the first level or the second level based on the signal to noise ratio.

11. The method of claim 1 further comprising verifying a build configuration.

12. The method of claim 11 wherein verifying the build configuration comprises performing a simulated side offset rigid barrier test on a baseline build configuration and an optimum design.

13. The method of claim 11 wherein verifying the build configuration comprises performing a simulated side offset rigid barrier test on a baseline build configuration and an optimum design for different regions of a front end module.

14. The method of claim 1 further comprising displaying a build configuration after verifying.

15. A system comprising:
a processor;
a non-transitory computer readable medium including instructions that are executable by the processor, wherein the instructions include,
forming a plurality of control factors for a front structure of a vehicle, each control factor comprising a first level and a second level;
selecting a first level or a second level for each control factor based on a crash velocity and an amount of energy absorbed; and
forming a vehicle design output corresponding to the first level or the second level for each control factor based on selecting.

16. The system of claim 15 wherein selecting the first level or the second level for each control factor is based on a signal to noise ratio
17. The system of claim 15 wherein prior to selecting the first level or a second level determining a plurality of build configurations comprising a plurality of different levels for each control factor.

18. The system of claim 15 further comprising verifying a build configuration by performing a simulated side offset rigid barrier test on a baseline build configuration and an optimum design.

19. The system of claim 15 wherein the instructions include verifying the build configuration by transmitting a vehicle design output through a network to a design verifier and performing a simulated side offset rigid barrier test on a baseline build configuration and an optimum design for different regions of a front end module.

20. The system of claim 19 wherein the instructions further comprise displaying a build configuration after verifying.
